(19) United States
(12) Patent Application Publication
(10) Pub. No.: US 2016/0249456 A1
(43) Pub. Date: Aug. 25, 2016

(54) APPARATUS FOR REDUCING NOISE IN ELECTRONIC DEVICE

(71) Applicant: Samsung Electronics Co., Ltd., Gyeonggi-do (KR)

(72) Inventors: Jonghyeok YOUN, Gyeonggi-do (KR); Jaehyung CHO, Gyeonggi-do (KR); Myungkyoon CHUNG, Gyeonggi-do (KR)

(21) Appl. No.: 14/993,523

(22) Filed: Jan. 12, 2016

(30) Foreign Application Priority Data
Feb. 23, 2015 (KR) 10-2015-0025269

(51) Int. Cl. H05K 1/18

(52) U.S. Cl. CPC H05K 1/18

(57) ABSTRACT

An electronic device with a reduced noise may include a printed circuit board and a signal creating unit mounted on the printed circuit board and configured to create at least one signal. The electronic device may also include at least one power via configured to connect a power terminal of the signal creating unit with a main power line disposed in the printed circuit board. The electronic device further includes at least one ground via configured to connect a ground terminal of the signal creating unit with a main ground disposed in the printed circuit board. In this electronic device, the ground via is disposed in parallel with the power via.

### CLAIM OF PRIORITY

This application claims the benefit under 35 U.S.C. §119(a) of Korean patent application filed on Feb. 23, 2015 in the Korean Intellectual Property Office and assigned Serial number 10-2015-0025269, the entire disclosure of which is hereby incorporated by reference.

### TECHNICAL FIELD

The present disclosure generally relates to an apparatus for reducing noise created in an electronic device.

### BACKGROUND

Mobile electronic devices, such as mobile communication terminals (e.g., smartphones), are widely used. Normally such electronic devices offer various functions needed by users. For example, the mobile communication terminal offers, inherently or optionally, a call function, a camera function, a broadcast receiving function, an internet access function, a voice recording function, and the like.

In order to offer such a variety of functions, the electronic device may have many electronic components equipped therein. These electronic components may generate signals of a specific frequency during operation.

Unfortunately, these signals may act as a noise and interfere with other electronic components. In this case, due to such interference, frequently other electronic components may operate improperly. Especially, if other electronic components are associated with audio functions (e.g., a call function, a music play function, etc.), the quality of audio may be deteriorated due to the interference.

Meanwhile, an increasing number of people suffer from some degree of hearing impairment. For example, it has been reported that 10% of Americans have hearing trouble and 80% of those wears a hearing aid. Also, it is known that about 0.5 billion people have hearing difficulties all over the world.

If a hearing-impaired person who uses a hearing aid places the electronic device (e.g., a smart phone) to the ear to talk over the phone, undesired phenomena such as howling often occur in the hearing aid. For this reason, recent electronic devices are required to meet Hearing Aid Compatibility (HAC) requirements.

The HAC requirements contain some items such as magnetic signal intensity, Signal-plus-Noise to Noise Ratio (SNNR), and frequency response. An electronic device is considered hearing-aid compatible if it meets specific conditions with regard to such items. For example, four ratings from T1 to T4 are used for electronic devices, based on magnetic signal intensity and SNNR.

According to the HAC requirements, the magnetic signal intensity of −18 dBA/m or more and the SNNR of 20 dB or more should be satisfied to obtain T3 or more rating. Here, for example, the SNNR is defined as a magnetic signal to noise ratio at 1 kHz band.

An electronic device that supports HAC uses in general a receiver having tele-coil (also referred to as T-coil). This receiver (hereinafter referred to as an HAC receiver) has an advantage in amplifying the magnetic signal intensity but has disadvantages in other features. For example, in comparison with a normal receiver having no tele-coil, the HAC receiver has a lower audio volume by about 10 dB and some problems such as a larger size and increased manufacturing cost because of having to embed the tele-coil in the receiver.

### SUMMARY

Accordingly, in order to obviate the above-discussed issues, one aspect of the present disclosure is provide means, such as methods and devices, to effectively reduce undesired noise or interference created in an electronic device that may otherwise disturb the operation of various components of the electronic device.

Additionally, various embodiments of the present disclosure may improve SNNR by mutually offsetting magnetic fields created by the flow of electric currents. For example, embodiments of this disclosure may mutually offset magnetic fields in each of three-dimensional directions (i.e., X-axis, Y-axis and Z-axis directions). Through this, embodiments of this disclosure may provide an electronic device that satisfies HAC requirements.

According to embodiments of the present disclosure, an electronic device may include: a printed circuit board; a signal creating unit mounted on the printed circuit board and configured to create at least one signal; at least one power via configured to connect a power terminal of the signal creating unit with a main power line disposed in the printed circuit board; and at least one ground via configured to connect a ground terminal of the signal creating unit with a main ground disposed in the printed circuit board, the ground via being disposed in parallel with the power via.

### BRIEF DESCRIPTION OF THE DRAWINGS

FIG. 1 is a perspective view illustrating an electronic device according to an embodiment of the present disclosure.

FIG. 2 is a schematic diagram illustrating a partial internal structure of an electronic device according to an embodiment of the present disclosure.

FIG. 3A is an exploded perspective view illustrating a printed circuit board of an electronic device according to an embodiment of the present disclosure.

FIG. 3B is a cross-sectional view illustrating a printed circuit board of an electronic device according to an embodiment of the present disclosure.

FIG. 4, FIG. 5, FIG. 6 and FIG. 7 are plan views illustrating a printed circuit board of an electronic device according to various embodiments of the present disclosure.

FIG. 8 is a table illustrating HAC measurement results of an electronic device with regard to the Z-axis according to an embodiment of the present disclosure.

FIG. 9 and FIG. 10 are exploded perspective views illustrating a printed circuit board of an electronic device according to other embodiments of the present disclosure.

### DETAILED DESCRIPTION

Hereinafter, various embodiments of the present disclosure will be described with reference to the accompanying drawings. Specific embodiments are shown in the drawings and the relevant detailed descriptions are given in corresponding sections, but there is no intention to limit various embodiments of the present disclosure to the particular forms disclosed herein. For example, the present disclosure may have various embodiments while modifications and changes may be made therein. Various embodiments of the present disclosure should be construed to cover all modifications, equivalents, and/or alternatives falling within the spirit and scope of the present disclosure. In the description of the drawings, identical or similar reference numerals are used to designate identical or similar elements.

As used in various embodiments of the present disclosure, the expressions “have”, “may have”, “include”, or “may include” and other conjugates are intended merely to denote existence of a certain feature (e.g., numeral, function, operation, or component, or a combination thereof), and should not be construed to initially exclude the existence of addition of one or more other features.

The expression “A or B”, “at least one of A and/or B”, or “one or mor of A or/and B” used in the present disclosure includes any or all of combinations of listed words. For example, the expression “A or B”, “at least one of A and B”, or “at least one of A or B” may include (1) at least one A, (2) at least one B, or (3) both at least one A and at least one B.

The expressions such as “first”, “second”, or the like used in various embodiments of the present disclosure may modify various component elements in the various embodiments regardless of the sequence and/or importance but are merely used to differentiate the elements and may not limit corresponding component elements. For example, a first user device and a second user device indicate different user devices, regardless of the sequence or importance. For example, a first element may be termed a second element, and likewise a second element may also be termed a first element without departing from the scope of various embodiments of the present disclosure.

In the case where an element (e.g., a first element) is referred to as being “(operatively or communicatively) coupled with/to” or “connected” to another element (e.g., a second element), it should be understood that not only the element is directly connected to the other element, but also another element (e.g., a third element) may exist between them. Contrarily, when an element (e.g., a first element) is referred to as being “directly coupled” or “directly connected” to another element (e.g., a second element), it should be understood that no element (e.g., a third element) is interposed therebetween.

The phrase “configured to” in the present disclosure can, for example, be changed to “suitable for,” “having the capacity to,” “designed to,” “adapted to,” “made to,” or “capable of” The term “configured to” does not always refer to elements specifically designed in their hardware. In other situations, the term “configured to” can refer that the device is capable of an operation with another device or other components. For example, the phrase “a processor configured to execute A, B, and C” can refer to a dedicated processor (e.g., an embedded processor) that executes the operations or a generic-purpose processor (e.g., a CPU or an application processor) that executes the operations by executing at least one software program stored in a memory device.

The terms as used in embodiments of the present disclosure are used to describe a specific embodiment, and are not intended to limit the scope of another embodiment. As used herein, the singular forms are intended to include the plural forms as well, unless the context clearly indicates otherwise. Unless defined differently, all terms used herein, which include technical terminologies or scientific terminologies, have the same meaning as understood by a person skilled in the art to which the present disclosure belongs. Such terms as those defined in a generally used dictionary are to be interpreted to have the meanings equal to the contextual meanings in the relevant field of the art, and are not to be interpreted to have ideal or excessively formal meanings unless clearly defined in the present disclosure. According to certain conditions, terms defined in the present disclosure cannot be interpreted to exclude the embodiments of the present disclosure.

For example, the electronic device in various embodiments of the present disclosure may include at least one of a smartphone, a tablet Personal Computer (PC), a mobile phone, a video phone, an electronic book (e-book) reader, a desktop PC, a laptop PC, a netbook computer, a workstation, a server, a Personal Digital Assistant (PDA), a Portable Multimedia Player (PMP), an MP3 player, a mobile medical appliance, a camera, or a wearable device. According to various embodiments, wearable devices may include, for example, at least one of an accessory type (e.g., a watch, a ring, a bracelet, a necklace, glasses, contact lenses, a Head-Mounted Device (HMD)), a fabric or clothes type (e.g., electronic clothes), a skin adhesive type (e.g., a skin pad, a tattoo), or a body transplant type (e.g., an implantable circuit).

The electronic device according to various embodiments of the present disclosure may be a combination of one or more of the aforementioned various devices. Further, the electronic device according to various embodiments of the present disclosure may be a flexible device. Further, it will be apparent to those skilled in the art that the electronic device according to various embodiments of the present disclosure is not limited to the aforementioned devices.

Hereinafter, an electronic device according to various embodiments of the present disclosure will be described with reference to the accompanying drawings. The term “user” of the present disclosure may refer to a person who uses an electronic device or a device (e.g., an artificial intelligence electronic device) that uses an electronic device.

Furthermore, well known or widely used techniques, elements, structures, and processes may not be described or illustrated in detail to avoid obscuring the essence of the present disclosure. Although the drawings represent exemplary embodiments, the drawings are not necessarily to scale and certain features may be exaggerated or omitted in order to better illustrate and explain the present disclosure. Through the drawings, the same or similar reference numerals denote corresponding features consistently.

In the following embodiments, noises created in an electronic device may be removed (or reduced or offset) effectively. For example, various embodiments of this disclosure may effectively remove a noise induced by at least one signal (e.g., a flow of electric currents) created at a signal creating unit (e.g., a battery coupling unit). For this, in various embodiments, a power via which connects a power terminal of the signal creating unit with a main power line may be disposed in parallel with a ground via which connects a ground terminal of the signal creating unit with a main ground. In this case, the direction of electric currents which flow through the power via is opposite to the direction of electric currents which flow through the ground via. Therefore, magnetic fields created by electric currents flowing through the power via and the ground via may be offset by each other. Namely, a noise induced at the signal creating unit may be removed (or reduced). This method for removing a noise may be favorably applied to electronic devices configured to support Hearing Aid Compatibility (HAC). Hereinafter, it is supposed that an electronic device supports HAC and also the signal creating unit is a battery coupling unit.

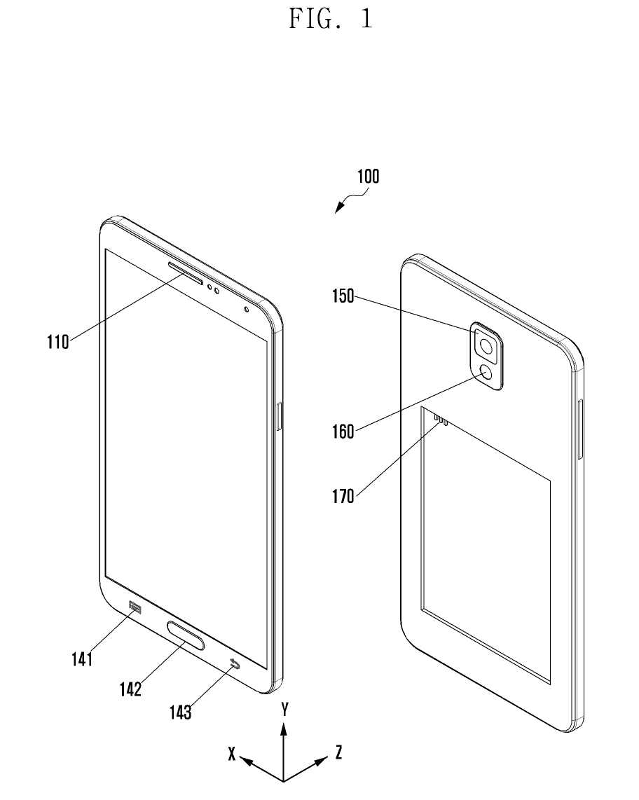

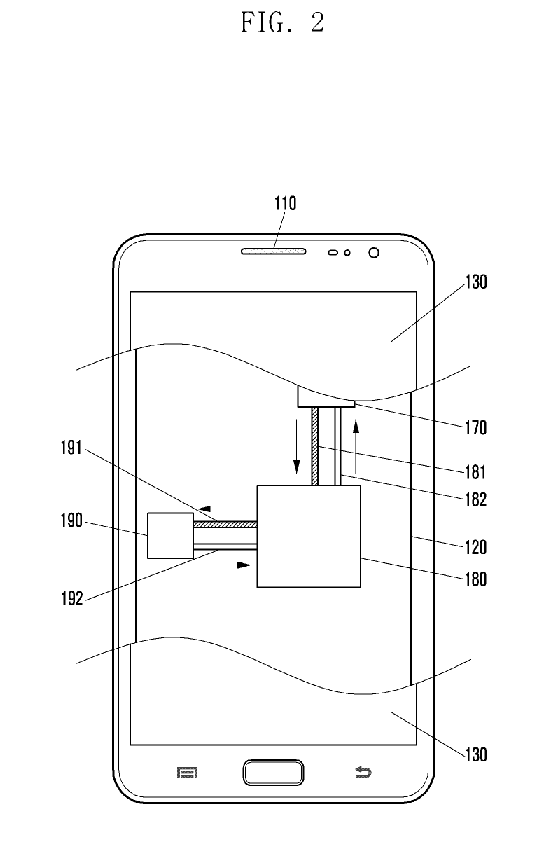

FIG. 1 is a perspective view illustrating an electronic device according to an embodiment of the present disclosure. FIG. 2 is a schematic diagram illustrating a partial internal structure of an electronic device according to an embodiment of the present disclosures.

Referring to FIGS. 1 and 2, an electronic device 100 according to an embodiment of this disclosure may be formed of a rectangular bar type mobile terminal. The electronic device 100 is merely an exemplary embodiment and is not intended to limit the present disclosure thereto. Alternatively, for example, the electronic device 100 may be variously configured and may be of a slide type, a folder type, a flip type, or the like or may be configured as a flexible type.

The electronic device 100 may have a display unit 130 on the front side thereof. Also, a speaker or receiver 110 may be located at an upper part on the front side. The receiver 110 may offer a function to output an audio signal (e.g., a ringtone, a music sound, etc.). The receiver 110 may be a Hearing Aid Compatibility (HAC) receiver having a tele-coil or a normal receiver having no tele-coil.

The electronic device 100 may further have a plurality of keys located, e.g., at a lower part on the front side. For example, the plurality of keys may include a menu key 141, a home key 142, and a cancel key 143. Such keys may be formed as a button-type mechanical key or a touch key, or soft key.

The electronic device 100 may also have a camera 150 and a light or flash 160 at an upper part on the rear side thereof. The camera 150 may offer a function to capture an image or record a video. The flash 160 may emit light for photography for a short time (e.g., 0.3 sec).

The electronic device 100 may have a concave space configured to receive a battery (not shown) on the rear side thereof. The battery inserted in and mounted on the concave space may be connected with a Printed Circuit Board (PCB) 120 through a battery coupling unit 170. The PCB 120 is formed in the electronic device 100 as shown in FIG. 2, and the battery may supply electric power to a plurality of electronic components mounted on or embedded in the PCB 120.

Referring to FIG. 2, the PCB 120 may include, for example, at least one of the battery coupling unit 170, a power supply unit 180, and a power amplifying module 190. Although not shown, the PCB 120 may also have passive components, such as a resistor, a capacitor, and an inductor, and/or Integrated Circuit (IC) chips such as a Wi-Fi module, a processor, and a memory.

Meanwhile, the electronic device 100 may support an HAC. In order to support the HAC, the electronic device 100 should meet requirements of the HAC T-coil standard. The HAC T-coil standard requires magnetic signal intensity and Signal-plus-Noise to Noise Ratio (SNNR) with regard to the X-axis, the Y-axis, and the Z-axis, which correspond to a longitudinal direction, a widthwise direction, and a thickness direction of the electronic device 100, respectively. Namely, the electronic device 100 that supports HAC should satisfy requirements about magnetic signal intensity and SNNR in a three-dimensional space.

The electronic device 100 according to an embodiment of this disclosure may reduce a noise (e.g., an audio band magnetic noise) induced at the receiver 110, thus meeting the HAC requirements, i.e., at least a T3 rating.

Noises or interference may be produced by impulse-type power consumption of a power amplifier module in the electronic device that adopts a GSM communication system, namely, a Time Division Multiple Access (TDMA) modulation system. Similarly, noises or interference may be produced by impulse-type power consumption of a processor, a power management integrated circuit, a buck, a low drop output, and the like.

Specifically, in the TDMA modulation system, one frame is formed of eight time slots, and a data transmission/reception period (T) may be about 4.615 ms which corresponds to a frequency of 217 Hz. The maximum power obtained by the TDMA modulation system is 33 dBm, which corresponds to high power output of about 2 W. In this case, the power amplifying module 190 may require high electric currents (e.g., 2 A). Namely, the power amplifying module 190 may incur impulse-type power consumption. At this time, a high electric current may flow along a power line of the battery coupling unit 170 while creating a magnetic field. This magnetic field created at the battery coupling unit 170 may affect, as a noise, other electronic components (e.g., the receiver). Namely, the battery coupling unit 170 may act as a noise source to other electronic components.

Specifically, when the power amplifying module 190 is operating, the electric power of the battery may be supplied to the power supply unit 180 through the first line 181 and returned to the battery through the second line 182. Also, the electric power of the power supply unit 180 may be supplied to the power amplifying module 190 through the third line 191 and returned to the power supply unit 180 through the fourth line 192.

When electric currents are flowing through lines 181, 182, 191, and 192, the magnetic field is created in the direction of fingers of right hand wound around each line according to Ampere's law. This magnetic field may act as a noise. For example, the magnetic field may create a noise (e.g., an audio band magnetic noise) to the electronic device 100 that supports the HAC, resulting in a reduction in the SNNR of the electronic device 100.

Meanwhile, if the battery coupling unit 170 is disposed at an upper part of the electronic device 100 and thereby located near the receiver 110, the noise may have a greater effect on the receiver 110 due to such proximity. In this case, the SNNR of the electronic device 100 may rapidly deteriorate. However, the noise may be minimized or reduced because electric currents flow in opposite directions along the first and second lines 181 and 182 disposed in parallel, the magnetic fields created from the first and second lines 181 and 182 may be offset (or reduced) by each other. Similarly, the magnetic fields created from the third and fourth lines 191 and 192 may be offset (or reduced) by each other. This may enhance the SNNR of the electronic device 100 according to an embodiment of this disclosure.

As discussed above, the parallel arrangement of the first line 181 and second line 182 may improve SNNR in the X-axis direction, and also the parallel arrangement of the third line 191 and fourth line 192 may improve SNNR in the Y-axis direction. This particular configuration is merely exemplary and is not to be considered as being limited thereto. Alternatively, the first line 181 and second line 182 may be arranged in parallel in the Y-axis direction, and also the third line 191 and fourth line 192 may be arranged in parallel in the X-axis direction.

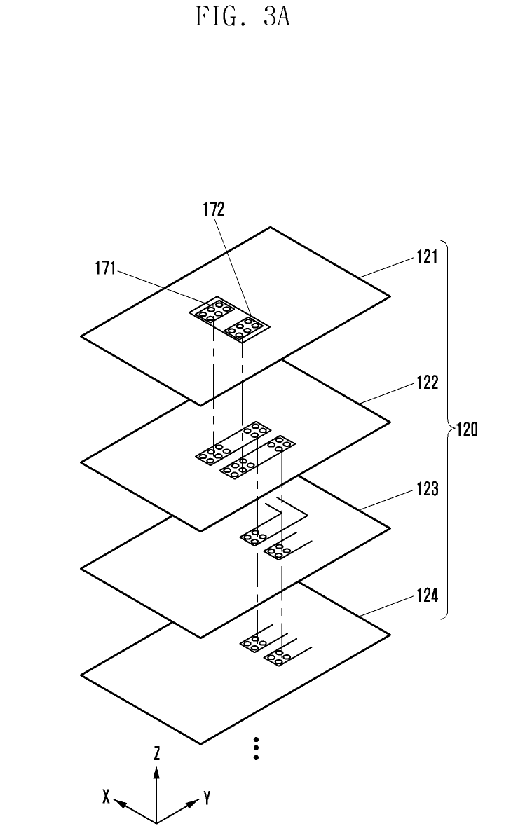

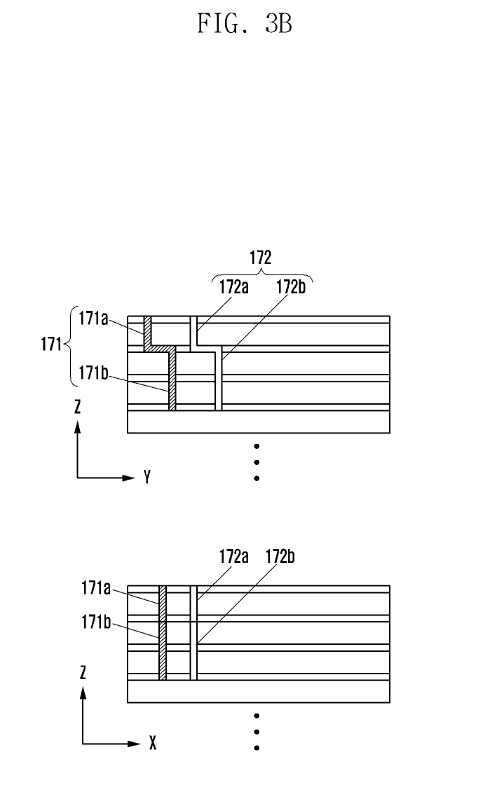

Further, in order to improve SNNR in the Z-axis direction, the electronic device 100 according to an embodiment of this disclosure may have a power wiring through-hole or via and a ground wiring through-hole or via which are disposed in parallel. Hereinafter, a related description will be made with reference to FIGS. 3A and 3B.

FIG. 3A is an exploded perspective view illustrating a printed circuit board of an electronic device according to an embodiment of the present disclosure. FIG. 3B is a cross-sectional view illustrating a printed circuit board of an electronic device according to an embodiment of the present disclosure.

Referring to FIGS. 3A and 3B, a printed circuit board (PCB) 120 according to an embodiment of this disclosure may be formed of two or more layers, i.e., multi-layer. The first layer 121 of the PCB 120 may have a power terminal including power vias 171a, 171b and a ground terminal including 172a, 172b formed therein.

The power terminal 171 may be connected with a main power line through a plurality of power vias. For example, as shown in FIG. 3B, the PCB 120 may have an electric connection between the first and second layers 121 and 122 through the first power via 171a and also have an electric connection among the second, third and fourth layers 122, 123 and 124 through the second power via 171b which may be disposed apart from the first power via 171a in the Y-axis direction. Each of the first and second power vias 171a and 171b may include a plurality of vias.

Similarly, the ground terminal 172 may be connected with a main ground through a plurality of ground vias. For example, as shown in FIG. 3B, the PCB 120 may have an electric connection between the first and second layers 121 and 122 through the first ground via 172a and also have an electric connection among the second, third and fourth layers 122, 123 and 124 through the second ground via 172b which is disposed apart from the first ground via 172a in the Y-axis direction. Each of the first and second ground vias 172a and 172b may include a plurality of vias.

The first power via 171a and the first ground via 172a may be disposed in parallel in the Z-axis direction, and also the second power via 171b and the second ground via 172b may be disposed in parallel in the Z-axis direction. The power via 171a or 171b and the adjacent ground via 172a or 172b may be located within a short distance (e.g., 3 cm) for allowing the magnetic fields to be offset. A long distance may fail to cause the magnetic fields created from the power via 171a or 171b and the adjacent ground via 172a or 172b to be offset.

Like the above, the parallel arrangement of the power via and the ground via may improve SNNR in the Z-axis direction.

Although FIGS. 3A and 3B illustrate two power vias and two ground vias used for connections from the first layer 121 to the fourth layer 124, a greater or lesser number of vias may be used without departing from the scope and spirit of the present disclosure. Alternatively, such layers may be connected through a single power via and a single ground via.

Further, although FIGS. 3A and 3B illustrate the power vias 171a and 171b or the ground vias 172a and 172b disposed apart from each other in the Y-axis direction, this is also exemplary and not limiting. Alternatively, the power vias 171a and 171b or the ground vias 172a and 172b may be disposed apart from each other in the X-axis direction or in the X-axis and Y-axis directions.

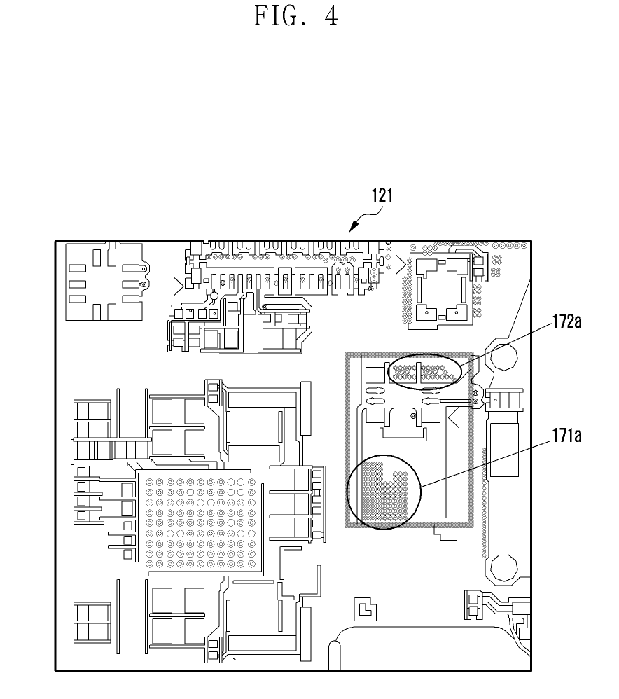

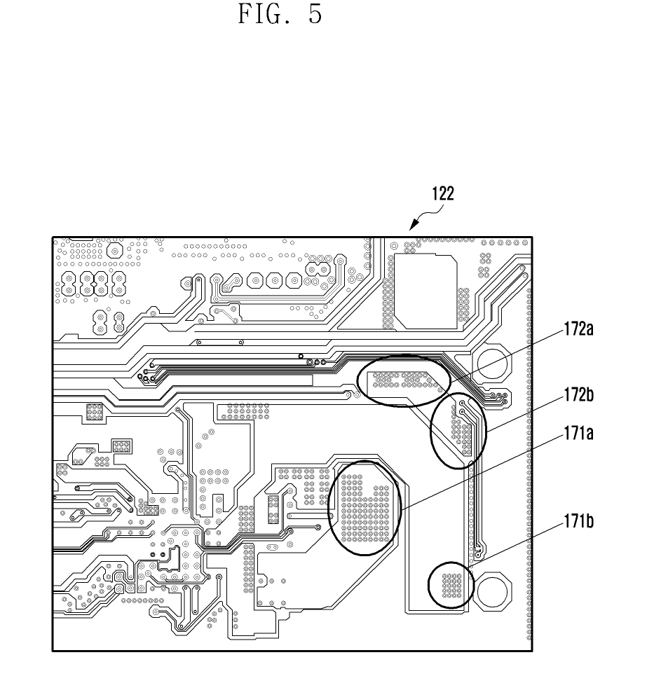

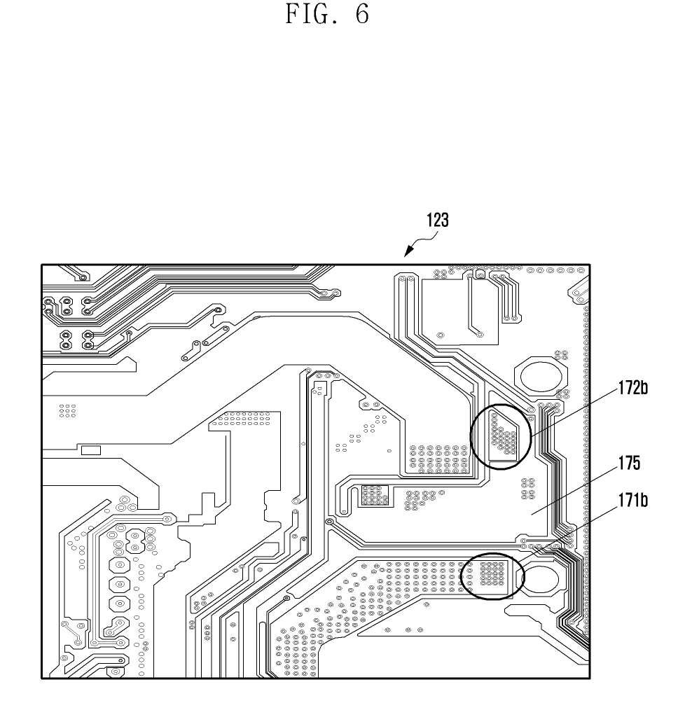

FIGS. 4 to 7 are plan views illustrating a printed circuit board of an electronic device according to various embodiments of the present disclosure.

Referring to FIGS. 4 to 7, the first layer 121 of the PCB 120 may have the first power via 171a and the first ground via 172a which are formed in a specific area onto which the battery coupling unit (not shown) is mounted. Each of the first power via 171a and the first ground via 172a may include a plurality of vias.

The second layer 122 may have the first power via 171a, the first ground via 172a, the second power via 171b, and the second ground via 172b. Each of the first power via 171a, the first ground via 172a, the second power via 171b, and the second ground via 172b may be formed of a plurality of vias.

The third layer 123 may have the second power via 171b and the second ground via 172b. The second ground via 172b may be separated from a neighboring ground 175 so as to form a separate path for removing an audio band magnetic noise.

The fourth layer 124 may have a main ground 176, the second power via 171b, and the second ground via 172b. The main ground 176 may have a ground line 172c disposed in parallel with a main power line 171c at some length. The second power via 171b may be connected with the main power line 171c, and the second ground via 172b may be connected with the ground line 172c. Therefore, as discussed above, audio band magnetic noises created in the X-axis, Y-axis, and Z-axis directions near the battery coupling unit may be offset by each other, and thereby SNNR may be improved in the X-axis, Y-axis, and Z-axis directions.

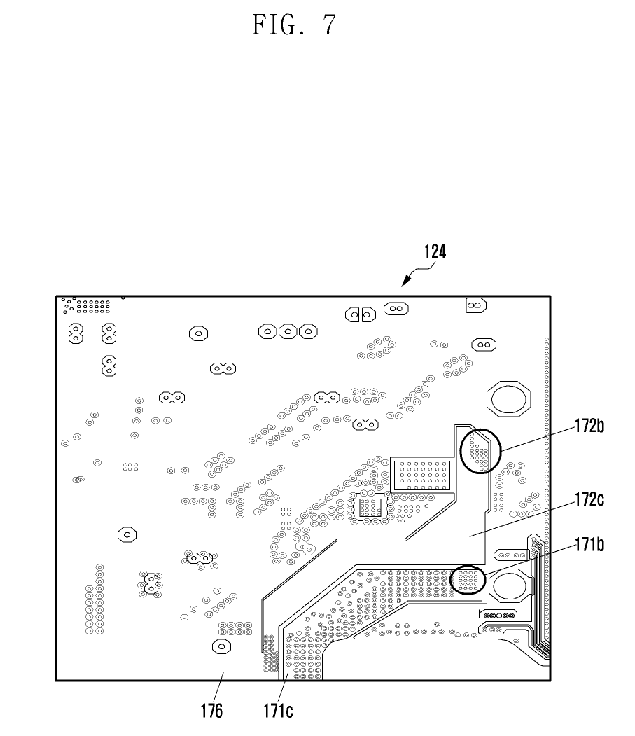

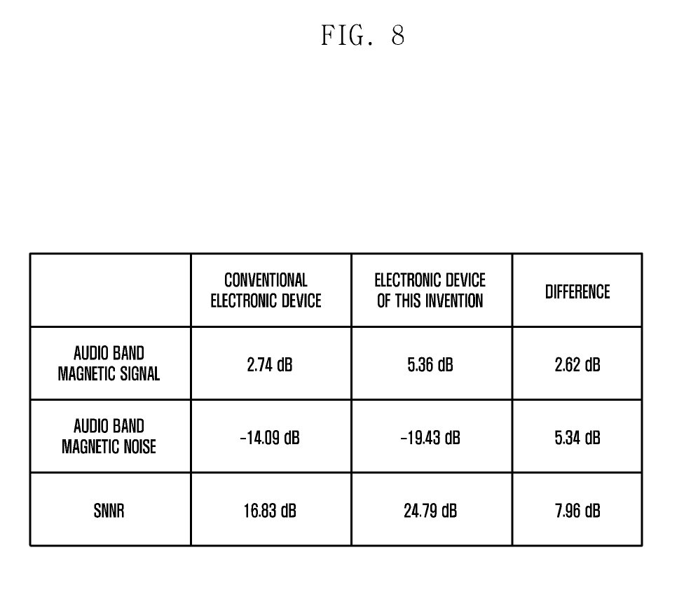

FIG. 8 is a table illustrating HAC measurement results of an electronic device with regard to the Z-axis according to an embodiment of the present disclosure.

Referring to FIG. 8, in a conventional electronic device in which a power via and a ground via are not disposed in parallel with each other, the audio band magnetic signal, the audio band magnetic noise, and the SNNR were measured as 2.74 dB, −14.09 dB, and 16.83 dB, respectively. This result, for example, would fail to obtain a T3 rating according to the HAC requirements.

On the other hand, in the electronic device 100 having parallel arrangements between the power via and the ground via according to this disclosure, the audio band magnetic signal, the audio band magnetic noise, and the SNNR were measured as 5.36 dB, −19.43 dB, and 24.79 dB, respectively. This, for example, would obtain T3 rating according to the HAC requirements. Namely, the electronic device 100 according to this disclosure has an improved SNNR through the improvement of the audio band magnetic noise with regard to the Z-axis direction.

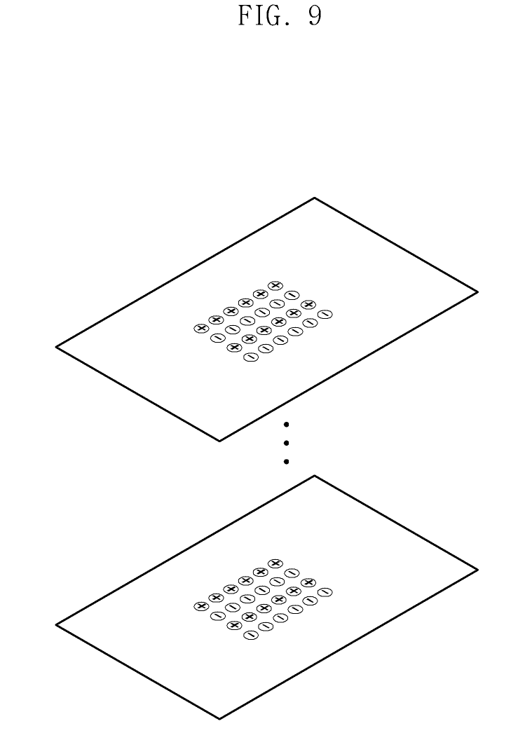

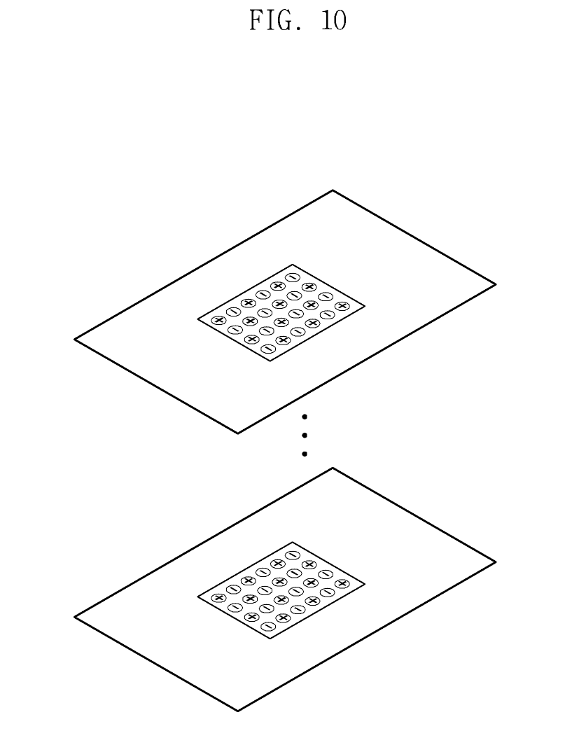

FIGS. 9 and 10 are exploded perspective views illustrating a printed circuit board of an electronic device according to other embodiments of the present disclosure.

Referring to FIGS. 9 and 10, the power vias and the ground vias may be disposed in some rows and in some columns.

According to a certain embodiment, a plurality of power vias may be disposed in a row, and also a plurality of ground vias may be disposed in a row. For example, as shown in FIG. 9, the power vias may be arranged to form the first row and the third row, and the ground vias may be arranged to form the second row and the fourth row. Alternatively, the power vias may be disposed in a single row, and similarly the ground vias may be disposed in a single row.

According to a certain embodiment, the power vias and the ground vias may be disposed by turns in rows and/or columns. For example, as shown in FIG. 10, the power vias may be disposed at points (1, 1), (1, 3), (2, 2), (2, 4), (3, 1), (3, 3), etc., and the ground vias may be disposed at points (1, 2), (1, 4), (2, 1), (2, 3), (3, 2), (3, 4), etc. wherein a point (i, j) means the i-th row and the j-th column.

In the above-discussed embodiments, the power via for connecting the power terminal of the battery coupling unit with the main power line is disposed in the Z-axis direction and in parallel with the ground via for connecting the ground terminal of the battery coupling unit with the main ground. As will be understood by those skilled in the art, this may be applied to any part, creating a magnetic field by means of an electric current, other than the battery coupling unit. For example, it is possible to prevent at least one signal, created at any signal creating unit, from acting as a noise to other electronic components. This signal may be created at any line for connecting the signal creating unit with other electronic components. In such cases, at least one power via for connecting a power terminal of the signal creating unit with a main power line in the printed circuit board may be disposed in parallel with at least one ground via for connecting a ground terminal of the signal creating unit with a main ground in the printed circuit board.

As fully discussed hereinbefore, various embodiments of this disclosure may effectively reduce a noise created in the electronic device. For example, some embodiments of this disclosure may mutually offset (or reduce) an audio band magnetic noise. Therefore, the electronic device according to this disclosure may obtain the HAC certification of higher rating (e.g., T3 or more) without using an HAC receiver. Also, the electronic device of this disclosure may offer an audio signal of improved quality to hearing-aid users.

Furthermore, according to embodiments of this disclosure, it is possible to freely determine the position of a signal creating unit (e.g., a battery coupling unit) since a noise induced at the signal creating unit can be effectively removed. This may also improve the degree of freedom in design of the electronic device.

While the disclosure has been particularly shown and described with reference to an exemplary embodiment thereof, it will be understood by those skilled in the art that various changes in form and details may be made therein without departing from the spirit and scope of this disclosure as defined by the appended claims.

What is claimed is:

1. An electronic device comprising:
a printed circuit board including a main power line and a main ground;
a signal creating unit including a power terminal and a ground terminal mounted on the printed circuit board, and configured to create at least one signal;
at least one power via configured to connect the power terminal with the main power line; and
at least one ground via configured to connect the ground terminal with the main ground, wherein the ground via is disposed in parallel with the power via.

2. The electronic device of claim 1, wherein the power via and the ground via are positioned under the signal creating unit.

3. The electronic device of claim 1, further comprising:
a receiver configured to output an audio signal,
wherein the signal creating unit is disposed at an upper part of the electronic device and located near the receiver.

4. The electronic device of claim 3, wherein the receiver does not comprises tele-coil.

5. The electronic device of claim 1, wherein the power via and the ground via are disposed by turns in a single row or column.

6. The electronic device of claim 1, wherein the power via and the ground via are disposed by turns in two or more rows or columns.

7. The electronic device of claim 1, wherein the power via and the ground via are disposed within a distance for allowing the offset of magnetic fields.

8. The electronic device of claim 1, wherein magnetic fields created by electric currents flowing through the power via and the ground via are offset by each other.

9. The electronic device of claim 1, wherein the ground via is formed independently from the main ground.

10. The electronic device of claim 1, wherein the main ground includes a ground line disposed in parallel with the main power line at length.

11. The electronic device of claim 10, wherein magnetic fields created by electric currents flowing through the main power line and the ground line are offset by each other.

12. The electronic device of claim 1, wherein the electronic device supports hearing aid compatibility (HAC).

13. The electronic device of claim 1, wherein the signal creating unit is a battery coupling unit configured to connect a battery with the printed circuit board.

14. The electronic device of claim 1, wherein the at least one signal is generated from a connection line between the signal creating unit and other electronic component.
